(19) United States
(12) Patent Application Publication
(10) Pub. No.: US 2007/0232046 A1
(43) Pub. Date: Oct. 4, 2007

(54) Damascene interconnection having porous low K layer with improved mechanical properties

(76) Inventors: Koji Miyata, Mahopac, NY (US); Takeshi Nogami, Chappaqua, NY (US)

Correspondence Address: MAYER & WILLIAMS PC, 251 NORTH AVE. WEST, 2ND FLOOR, WESTFIELD, NJ, 07090, US

(21) Appl. No.: 11/395,762

(22) Filed: Mar. 31, 2006

(51) Int. Cl. H01L 21/44

(52) U.S. Cl. 438/597

(57) ABSTRACT

A method is provided for fabricating a damascene interconnection. The method begins by forming on a substrate a porous dielectric layer and imparting a porogen material into an upper portion of the porous dielectric layer to define a less porous dielectric sublayer within the dielectric layer. A capping layer is formed on the less porous dielectric sublayer and a resist pattern is formed over the capping layer to define a first interconnect opening. The capping layer and the dielectric layer are etched through the resist pattern to form the first interconnect opening. The resist pattern is removed and an interconnection is formed by filling the first interconnect opening with conductive material. The interconnection is planarized to remove excess conductive material.

### FIELD OF THE INVENTION

The present invention relates generally to single and dual damascene interconnections for integrated circuits, and more specifically to a single or dual damascene interconnection having a porous low k layer that is hardened by providing a less porous low k sub-layer therein.

### BACKGROUND OF THE INVENTION

The manufacture of integrated circuits in a semiconductor device involves the formation of a sequence of layers that contain metal wiring. Metal interconnects and vias which form horizontal and vertical connections in the device are separated by insulating layers or inter-level dielectric layers (ILDs) to prevent crosstalk between the metal wiring that can degrade device performance. A popular method of forming an interconnect structure is a dual damascene process in which vias and trenches are filled with metal in the same step to create multi-level, high density metal interconnections needed for advanced high performance integrated circuits. The most frequently used approach is a via first process in which a via is formed in a dielectric layer and then a trench is formed above the via. Recent achievements in dual damascene processing include lowering the resistivity of the metal interconnect by switching from aluminum to copper, decreasing the size of the vias and trenches with improved lithographic materials and processes to improve speed and performance, and reducing the dielectric constant (k) of insulators or ILDs by using so-called low k materials to avoid capacitance coupling between the metal interconnects. The expression “low-k” material has evolved to characterize materials with a dielectric constant less than about 3.9. One class of low-k material that have been explored are organic low-k materials, typically having a dielectric constant of about 2.0 to about 3.8, which may offer promise for use as an ILD.

Many of the low k materials, however, have properties that are incompatible with other materials employed to fabricate semiconductor devices or are incompatible with processes employed to fabricate the semiconductor devices. For example, adhesion to layers formed from a low dielectric constant material by adjacent layers is often poor, resulting in delamination. Additionally, layers formed from low dielectric materials are often structurally compromised by Chemical Mechanical Polishing (CMP) processes through erosion, as well as adsorption of CMP slurry chemicals. Etching processes often produce micro-trenches and rough surfaces in layers formed from materials having low dielectric constants, which is often unsuitable for subsequent photolithography processes. As a result, these materials are problematic to integrate into damascene fabrication processes. To overcome some of these problems a cap or capping layer typically formed from a material such as SiO₂ is employed to protect the low dielectric materials during the CMP processes. The cap layer also serves as a hardmask when the vias and trenches are etched.

Unfortunately the formation of the cap layer itself can damage the underlying low k material. Both the low k material and the cap layer are generally formed by a deposition process that is referred to as chemical vapor deposition or CVD. Conventional thermal CVD processes supply reactive gases to the substrate surface where heat-induced chemical reactions take place to produce a desired film. The high temperatures at which some thermal CVD processes operate can damage device structures having layers previously formed on the substrate. To overcome this problem, a method of depositing metal and dielectric films at relatively low temperatures is often employed. Such a method is referred to as plasma-enhanced CVD (PECVD) techniques, which are described, for example, in U.S. Pat. No. 5,362,526, entitled “Plasma-Enhanced CVD Process Using TEOS for Depositing Silicon Oxide”. Plasma-enhanced CVD techniques promote excitation and/or disassociation of the reactant or precursor gases by the application of radio frequency (RF) energy to a reaction zone near the substrate surface, thereby creating a plasma of highly reactive species. The high reactivity of the released species reduces the energy required for a chemical reaction to take place, and thus lowers the required temperature for such PECVD processes.

Recently, porous low k materials have been employed in damascene processes. A void-filled, or porous dielectric material has a lower dielectric constant than the fully dense void-free version of the same material. Such porous low-dielectric constant materials may be deposited by chemical vapor deposition (CVD), or may be spun on in liquid solution and subsequently cured by heating to remove the solvent. Porous low-dielectric constant materials are advantageous in that they have a dielectric constant of 3.0 or less. Examples of such porous low-dielectric constant materials include porous SiLK™ and porous silicon carbonated oxide, as examples. A porogen may be included in the porous low-dielectric constant materials to cause the formation of the pores.

However, problems arise in utilizing porous dielectric materials. The very nature of the desirable porous structure of these materials also make them fragile and easily damaged by CMP processes. Accordingly, it would be desirable to provide a damascene interconnect structure that includes a porous low k material to reduce the structure's overall dielectric constant but which is also less fragile to mechanical damage from CMP and other processes.

### SUMMARY OF THE INVENTION

In accordance with the present invention, a method is provided for fabricating a damascene interconnection. The method begins by forming on a substrate a porous dielectric layer and imparting a porogen material into an upper portion of the porous dielectric layer to define a less porous dielectric sublayer within the dielectric layer. A capping layer is formed on the less porous dielectric sublayer and a resist pattern is formed over the capping layer to define a first interconnect opening. The capping layer and the dielectric layer are etched through the resist pattern to form the first interconnect opening. The resist pattern is removed and an interconnection is formed by filling the first interconnect opening with conductive material. The interconnection is planarized to remove excess conductive material.

In accordance with one aspect of the invention, at least a portion of the porogen material is removed from the less porous dielectric sublayer.

In accordance with another aspect of the invention, the portion of porogen material is removed from the less porous dielectric sublayer by a thermal process.

In accordance with another aspect of the invention, the first interconnect opening comprises a via.

In accordance with another aspect of the invention, the first interconnect opening comprises a via and a trench connected thereto.

In accordance with another aspect of the invention, the planarizing step is performed by CMP.

In accordance with another aspect of the invention, the porogen material is imparted by a process selected from the group consisting of a thermal, plasma and spin-on process.

In accordance with another aspect of the invention, etching is performed by reactive ion etching (RIE).

In accordance with another aspect of the invention the step of forming the porous dielectric layer includes heating the porous dielectric layer at an elevated temperature to remove a thermally degradable porogen located therein.

In accordance with another aspect of the invention, the damascene interconnection is a dual damascene interconnection.

In accordance with another aspect of the invention, before forming the porous dielectric layer a lower interconnection is formed on the substrate and an etch stop layer is formed on the lower interconnection.

### BACKGROUND OF THE INVENTION

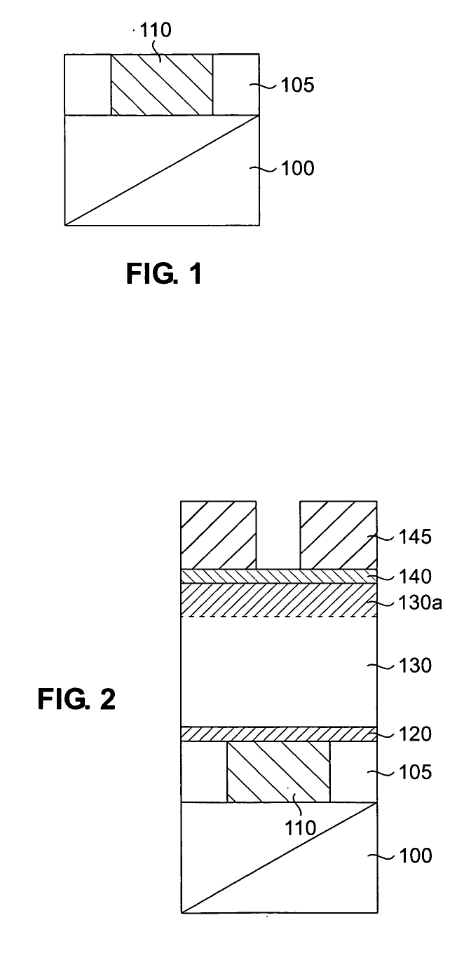

FIGS. 1-9 show cross-sectional views illustrating the formation of a dual damascene structure constructed in accordance with one embodiment of the present invention.

### DETAILED DESCRIPTION

The methods and structures described herein do not form a complete process for manufacturing semiconductor device structures. The remainder of the process is known to those of ordinary skill in the art and, therefore, only the process steps and structures necessary to understand the present invention are described herein.

The present invention can be applied to microelectronic devices, such as highly integrated circuit semiconductor devices, processors, micro electromechanical (MEM) devices, optoelectronic devices, and display devices. In particular, the present invention is highly useful for devices requiring high-speed characteristics, such as central processing units (CPUs), digital signal processors (DSPs), combinations of a CPU and a DSP, application specific integrated circuits (ASICs), logic devices, and SRAMs.

Herein, an opening exposing a lower interconnection is referred to as a via, and a region where interconnections will be formed is referred to as a trench. Hereinafter, the present invention will be described by way of an example of a via-first dual damascene process. However the present invention is also applicable to other dual damascene processes as well as single damascene processes.

In the present invention the aforementioned problems that can arise when a porous low k material is employed as an ILD layer and undergoes CMP processing. As detailed below, this can be accomplished by imparting or embedding a porogen material into a top or uppermost portion of the porous ILD layer so that the ILD layer is mechanically hardened. A method of fabricating dual damascene interconnections according to an embodiment of the present invention will now be described with reference to FIG. 1 through 9. Of course, the present invention is equally applicable to single damascene interconnect structure.

As shown in FIG. 1, a substrate 100 is prepared. A lower ILD layer 105 including a lower interconnection 110 is formed on the substrate 100. The substrate 100 may be, for example, a silicon substrate, a silicon on insulator (SOI) substrate, a gallium arsenic substrate, a silicon germanium substrate, a ceramic substrate, a quartz substrate, or a glass substrate for display. Various active devices and passive devices may be formed on the substrate 100. The lower interconnection 110 may be formed of various interconnection materials, such as copper, copper alloy, aluminum, and aluminum alloy. The lower interconnection 110 is preferably formed of copper because of its low resistance. Also, the surface of the lower interconnection 110 is preferably planarized.

Referring to FIG. 2, a barrier or etch stop layer 120, a low-k ILD layer 130, and a capping layer 140 are sequentially stacked on the surface of the substrate 100 where the lower interconnection 110 is formed, and a photoresist pattern 145 is formed on the capping layer 140 to define a via.

The barrier or etch stop layer 120 is formed to prevent electrical properties of the lower interconnection 110 from being damaged during a subsequent etch process for forming a via. Accordingly, the etch stop layer 120 is formed of a material having a high etch selectivity with respect to the ILD layer 130 formed thereon. In one embodiment, the etch stop layer 120 is formed of SiC, SiN, or SiCN, having a dielectric constant of 4 to 5. The etch stop layer 120 is as thin as possible in consideration of the dielectric constant of the entire ILD layer, but thick enough to properly function as an etch stop layer.

The ILD layer 130 is formed of a porous dielectric material. Typically, the porous dielectric material comprises a porous low-k material having a dielectric constant (k) value of 3.0 or lower. For example, the porous dielectric material may comprise a material having a k value of about 3.0 or less with a porogen introduced in order form pores, which lowers the dielectric constant to 2.7 or less, and more preferably about 2.5 or less, e.g. 1.8 or 1.9. Typically, the more pores formed in the material, the lower the dielectric constant k of the dielectric material will be. The ILD layer 130 may have a thickness of about 300 nm for a 45 nm gate half pitch technology, for example. Alternatively, the porous dielectric material may comprise other thicknesses. The porous dielectric material may be selected from a wide range of materials, including, without limitation, comprise porous methylsilsesquioxane (MSQ), porous inorganic materials, porous CVD materials, porous organic materials, or combinations thereof.

One widely used approach that can be employed to form porous low k materials relies on the incorporation of a thermally degradable material (porogen) within a host thermosetting matrix. Upon heating, the matrix material crosslinks, and the porogen undergoes phase separation from the matrix to form nanoscopic domains. Subsequent heating leads to porogen decomposition and diffusion of the volatile by-products out of the matrix. Under optimized processing conditions, a porous network results in which the pore size directly correlates with the original phase-separated morphology. Two commercially available materials of this type are Dow Chemical's porous SiLK and IBM's DendriGlass materials.

Dendriglass is a chemical composition containing MSQ and various amounts of a second phase polymeric material, i.e. a pore-forming agent. Dendriglass can be made into a porous film with a dielectric constant in a range between about 1.3 and about 2.6 depending on the amount of the second phase material added to the film. The second phase polymeric material, or the pore-forming agent, is a material that is usually a long chained polymer which can be decomposed and volatilized and driven from the matrix material, i.e. MSQ, after the film has been cured in a first curing process. Dendriglass can be spin-coated and then cured temperature at a temperature of less than about 350° C. Finally, the completely etched structure is heated to a temperature higher than the first temperature, or preferably higher than about 400° C. to 450° C., for a time period long enough to drive out the second phase polymeric material from the Dendriglass resulting in a porous low-k dielectric film.

In accordance with the present invention, after formation of the porous ILD layer 130, an uppermost portion of the ILD layer 130 (e.g., ILD layer 130a in FIG. 2) is refilled with a porogen material to increase its hardness. In one embodiment of the invention, the thickness of ILD layer 130a may range from about 10-50 nm for a 45 nm gate half pitch technology. By making the uppermost portion of the ILD layer 130 less or non-porous, its mechanical strength is advantageously increased. In this way the ILD layer will be less susceptible to damage during the subsequent formation of the capping layer 140 and CPM processing.

The porogen material that is introduced into the uppermost ILD layer 130a will generally depend on the particular composition of the porous low k material of which ILD layer 130 is comprised. For example, the porogen that is introduced may be an organic polymer. The porogen may be introduced by thermal, plasma, or spin-on processes.

By way of example and not as a limitation on the invention, if thermal processes are employed, a silicon containing gas such as SiH₄, Si₂H₆ and TEOS may be diffused into the ILD layer 130. The porogen that is deposited will be a silicon-based byproduct. Alternatively, a carbon containing gas such as C₂H₂ and C₂H₄ may be diffused into the ILD layer 130, in which case the porogen will be carbon or a carbon-based material. Likewise, if a plasma process is employed silicon containing gases such as SiH₄, Si₂H₆ and TEOS or carbon containing gases such as CH₄, CH₃OH, C₂H₆ may be used. If a spin-on process is employed, a silicon containing material such as an organo-silicon material in solvent may be applied and cured, after which the bulk portion may be removed. Alternatively, the spin-on process may use a carbon containing material such as polyarylethyel, the bulk portion of which is removed after it is applied and cured.

Referring again to FIG. 2, after formation of uppermost ILD layer 130a, capping layer 140 is formed thereabove. The capping layer 140 prevents the ILD layer 130 from being damaged when damascene interconnections are planarized using chemical mechanical polishing (CMP). The capping layer 140 also serves as a hardmask during the subsequent etching steps used to form vias and trenches. The capping layer 140 may be formed of any appropriate material such as SiO₂, SiOF, SiON, SiCOH, SiC, SiN, or SiCN. For example, in conventional processes an organosilicon compound such as tetraethoxysilane (TEOS) is used to form an SiO₂ capping layer by PECVD.

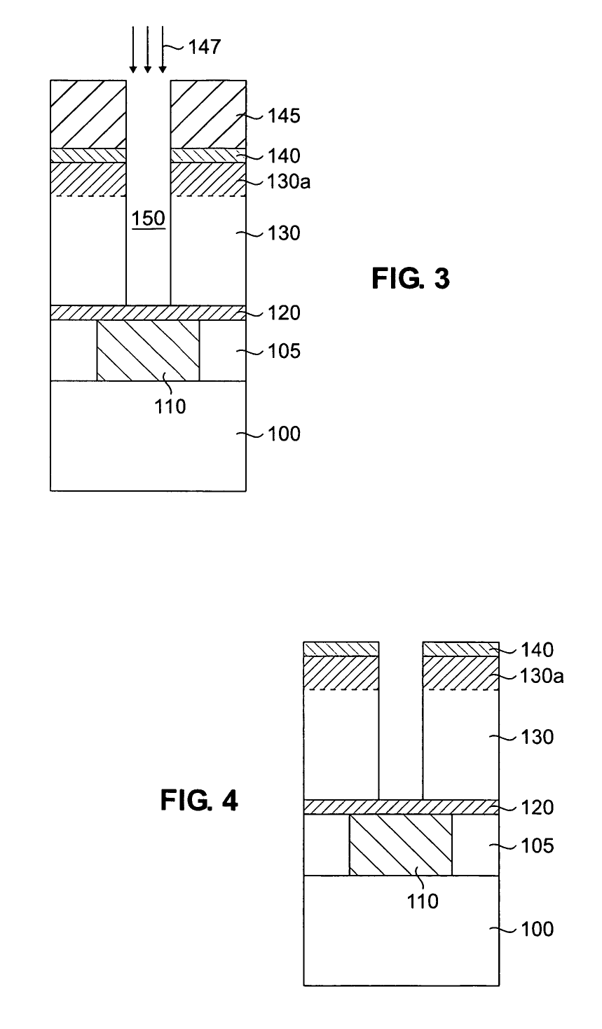

After formation of ILD layer 130 (and layer 130a) and capping layer 140, the process continues by forming the via photoresist pattern 145 by depositing a layer of a photoresist and then performing exposure and developing processes using a photo mask defining a via. Referring to FIG. 3, the ILD layer 130 is anisotropically etched (147) using the photoresist pattern 145 as an etch mask to form a via 150. The ILD layer 130 can be etched, for example, using a reactive ion beam etch (RIE) process, which uses a mixture of a main etch gas (e.g., CₓF_{y} and CₓH_{y}F_{z}), an inert gas (e.g. Ar gas), and possibly at least one of O₂, N₂, and COₓ. Here, the RIE conditions are adjusted such that only the ILD layer 130 is selectively etched and the etch stop layer 120 is not etched.

Referring to FIG. 4, the via photoresist pattern 145 is removed using a stripper. If the photoresist pattern 145 is removed using O₂-ashing, which is widely used for removing a photoresist pattern, the ILD layer 130, which often contains carbon, may be damaged by the O₂-based plasma. Thus, the photoresist pattern 145 alternatively may removed using an H₂-based plasma.

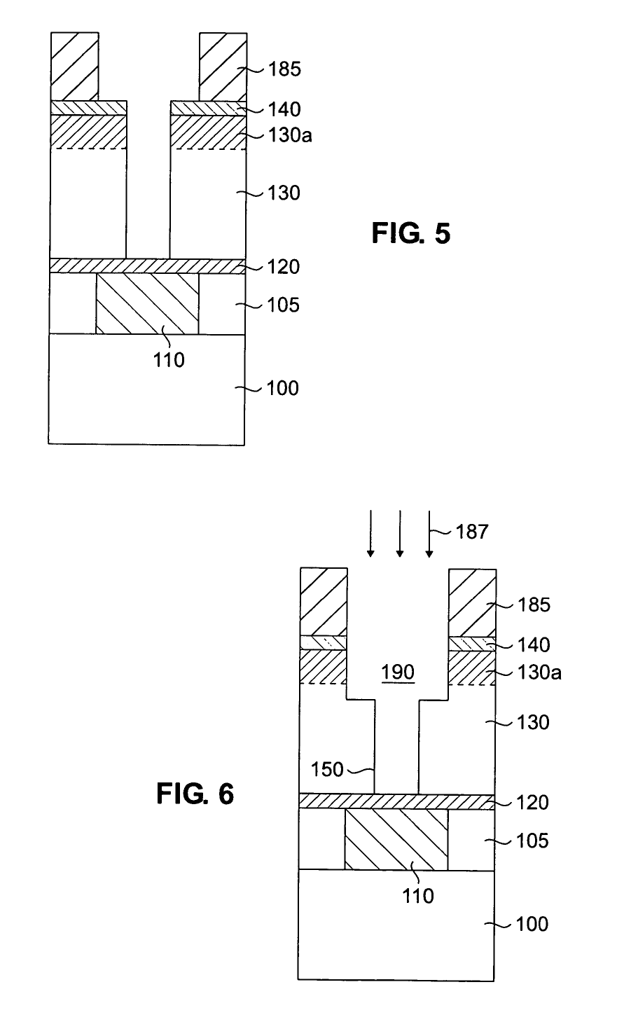

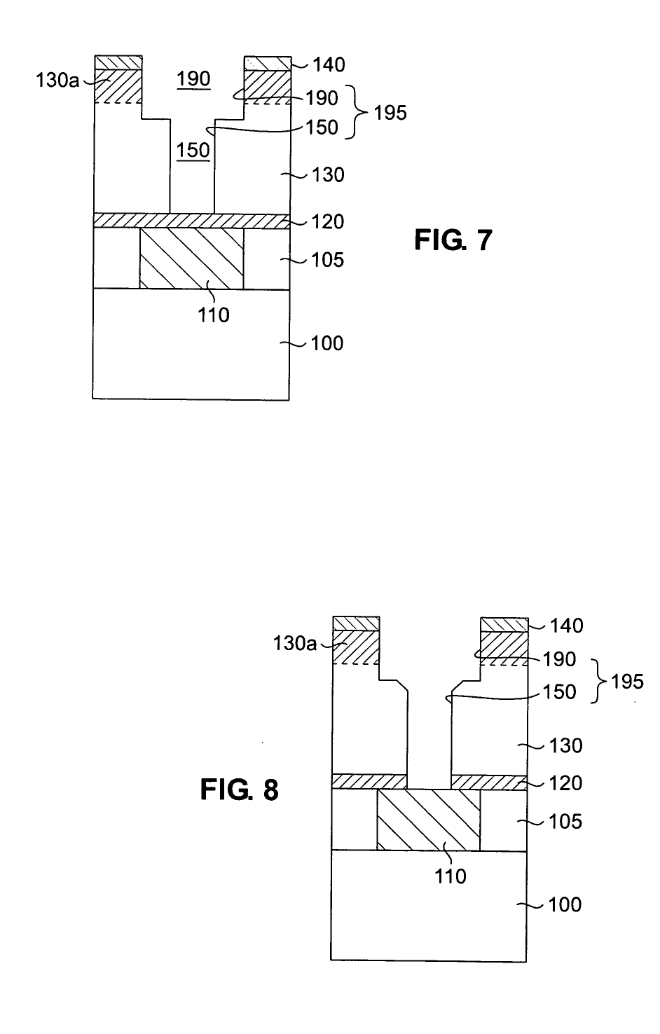

Referring to FIG. 5, a trench photoresist pattern 185 is formed, followed by formation of a trench 190 in FIG. 6. The capping layer 140 is etched using the photoresist pattern 185 as an etch mask, and then the ILD layer 130 is etched to a predetermined depth to form the trench 190. The resulting structure, shown in FIG. 7, defines a dual damascene interconnection region 195, which includes the via 150 and the trench 190.

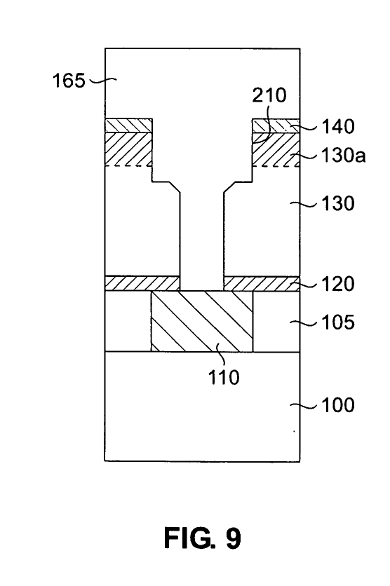

Referring to FIG. 8, the etch stop layer 120 exposed in the via 150 is etched until the lower interconnection 110 is exposed, thereby completing the dual damascene interconnection region 195. The etch stop layer 120 is etched so that the lower interconnection 110 is not affected and only the etch stop layer 120 is selectively removed. Next, the copper conductive layer is formed by an electroplating process. Referring to FIG. 9, the bulk copper layer 165 is formed on the dual damascene interconnection region 195. The excess metal above the interconnects is then removed by chemical mechanical polishing (CMP), thereby forming a dual damascene interconnection 210.

The porogens that fill uppermost ILD layer 130a may remain in the final structure. Alternatively, after the CMP process, the porogens may be removed by any appropriate technique. For instance, if the porogen is a thermally degradable material, it may be heated so that the porogen decomposes and the volatile by-products diffuse out of the structure.

Although various embodiments are specifically illustrated and described herein, it will be appreciated that modifications and variations of the present invention are covered by the above teachings and are within the purview of the appended claims without departing from the spirit and intended scope of the invention. For example, those of ordinary skill in the art will recognize that the via-first dual damascene process described with reference to FIGS. 1 through 9 can be applied to a trench-first dual damascene process.

1. A method of fabricating a damascene interconnection, the method comprising:
(a) forming on a substrate a porous dielectric layer;
(b) imparting a porogen material into an upper portion of the porous dielectric layer to define a less porous dielectric sublayer within the dielectric layer;
(c) forming a capping layer on the less porous dielectric sublayer;
(d) forming a resist pattern over the capping layer to define a first interconnect opening;
(e) etching the capping layer and the dielectric layer through the resist pattern to form the first interconnect opening;
(f) removing the resist pattern;
(g) forming an interconnection by filling the first interconnect opening with conductive material; and
(h) planarizing the interconnection to remove excess conductive material;

2. The method of claim 1 further comprising, after step (h), the step of removing the at least a portion of the porogen material from the less porous dielectric sublayer.

3. The method of claim 2 wherein the portion of porogen material is removed from the less porous dielectric sublayer by a thermal process.

4. The method of claim 1 wherein the first interconnect opening comprises a via.

5. The method of claim 1 wherein the first interconnect opening comprises a via and a trench connected thereto.

6. The method of claim 1 wherein the planarizing step is performed by CMP.

7. The method of claim 2 wherein the planarizing step is performed by CMP.

8. The method of claim 1 wherein the porogen material is imparted by a process selected from the group consisting of a thermal, plasma and spin-on process.

9. The method of claim 2 wherein the porogen material is imparted by a process selected from the group consisting of a thermal, plasma and spin-on process.

10. The method of claim 1 wherein the step of etching is performed by reactive ion etching (RIE).

11. The method of claim 1 wherein the step of forming the porous dielectric layer comprises heating the porous dielectric layer at an elevated temperature to remove a thermally degradable porogen located therein.

12. The method of claim 2 wherein the step of forming the porous dielectric layer comprises heating the porous dielectric layer at an elevated temperature to remove a thermally degradable porogen located therein.

13. The method of claim 1 wherein the damascene interconnection is a dual damascene interconnection and further comprising the steps of applying a second resist pattern over the capping layer and etching the dielectric layer to form a second interconnect opening that is connected to said first interconnect opening and in which interconnections will be formed.

14. The method of claim 1 further comprising, before step (a): forming a lower interconnection on the substrate; and forming an etch stop layer on the lower interconnection.

15. An integrated circuit having a damascene interconnection constructed in accordance with the method of claim 1.
